(19) United States
(12) Patent Application Publication
(10) Pub. No.: US 2004/0163600 A1
(43) Pub. Date: Aug. 26, 2004

(54) Vapor deposition device

(76) Inventors: Uwe Hoffmann, Alzenau (DE); Andreas Kloppel, Glauburg (DE); Andreas Jischke, Kahl (DE); Peter Sauer, Schluchtern (DE)

Correspondence Address: NEEDLE & ROSENBERG, P.C., SUITE 1000, 999 PEACHTREE STREET, ATLANTA, GA, 30309-3915, US

(21) Appl. No.: 10/720,989

(22) Filed: Nov. 24, 2003

(30) Foreign Application Priority Data
Nov. 30, 2002 (DE) 102 56 038.2-45

(51) Int. Cl. C23C 16/00

(52) U.S. Cl. 118/726

(57) ABSTRACT

A vapor deposition device for vapor deposition of vertically aligned regions of a substrate has an upright, electrically heated melting crucible having an electrical heater for the material to be vaporized. A nozzle pipe, which is separate from the melting crucible and is sealable on top, having a vapor outlet for vapor deposition of the substrate, is seated on the melting crucible. The nozzle pipe has a heater which is independent of the heater of the melting crucible.

### CROSS REFERENCE TO RELATED APPLICATIONS

The present application claims priority to German Patent Application No. 102 56 038.2-45, filed Nov. 30, 2002, which application is incorporated herein fully by this reference.

### BACKGROUND OF THE INVENTION

1. Field of the Invention

The present invention relates to a vapor deposition device for vapor deposition of vertically aligned regions of a substrate, in which an upright melting crucible, having a heater for melting and vaporizing material poured into the melting crucible, is positioned and which has a deflection device for deflecting the vapor flowing vertically out of the melting crucible horizontally toward the substrate.

2. Background Art

A vapor deposition device of the above-mentionied type is the object of DE 17 96 166 B2. In the vapor deposition device according to this publication, the material to be vaporized is vaporized using electron bombardment. The deflection device is formed by an electrode, positioned above the melting crucible, of the electrode system used for vaporization. The known vapor deposition device has the disadvantage that the horizontally flowing vapor does not tend to homogenize the distribution of its vapor particles and flows over a very large cross-section toward the substrate. Furthermore, there is the danger that the deflection device will be coated, through which its effect will be reduced. Since the known vapor deposition device requires heating using electron bombardment, it has only a relatively low output.

A vapor deposition device is also already known from U.S. Pat. No. 4,880,960, in which, instead of a melting crucible a relatively long, upright cylinder is used, which is sealed on its upper end and is heated over its entire length by an electrical resistance heater. The cylinder has a window in its lateral surface as a vapor outlet, which is covered on the outside by a screen, so that material to be vaporized which reaches the inside of the cylinder from above may not fall out directly through the window. The cylinder is concentrically enclosed on the outside by multiple reflectors, which have a vapor passage window for the passage of the vapor.

The known vapor deposition device is intended for the vaporization of magnesium. Magnesium has the property of sublimating in vacuum at temperatures of approximately 500° C. Therefore, according to U.S. Pat. No. 4,880,960, this magnesium is continuously introduced from above into the cylinder in the form of powder having a grain size of 0.3 to 2.5 mm. As the powder falls down, it changes into vapor, which leaves the cylinder via its vapor outlet because of the thermal radiation. Since the powder is present in the cylinder over its entire length, the vapor outlet must be covered by a screen, because otherwise solid particles would be able to leave the vapor deposition device with the vapor and reach the substrate. The arrangement of such a screen is to prevent exit of powder. However, in practice, this may not be completely precluded since a screen may in principle only retain those solid particles which are larger than its mesh width and the particles introduced become smaller through the vaporization until they are completely vaporized. These fine solid particles may reach the substrate to be coated through the screen.

### SUMMARY OF THE INVENTION

The present invention is based on the object of implementing a vapor deposition device of the above-mentioned type so that the vapor originating from a melting crucible and rising in the vertical direction is deflected with lobar distribution in such a way that a uniform distribution results and no solid particles are able to reach the substrate to be coated from the vaporizer.

This object is achieved according to the present invention in that the deflection device is a nozzle pipe, placed from above on the melting crucible and sealable on top, which has a horizontal vapor outlet in its lateral surface, and the nozzle pipe has a heater which is independent of the heater of the melting crucible.

Such a vapor deposition device has a typical melting crucible, into which the product to be vaporized may be introduced as such large, solid particles that initially a melt results, through which the vapor to be generated is subsequently produced. Therefore, no fine particles may reach the substrate with the vapor. According to the present invention, the function of vapor generation and vapor delivery to the substrate are separated from one another. Since the melting crucible and the nozzle pipe are heatable independently of one another by the separate heaters, it may be ensured during the operation of the vapor deposition device that the temperature in the nozzle pipe is always 100° C. to 200° C. higher than in the melting crucible, so that no condensation of vapor in the nozzle pipe and therefore no coating of the nozzle pipe may occur. Due to the use of a typical melting crucible, the vapor deposition device according to the present invention is capable of melting and vaporizing greatly differing materials, such as Al, Ag, Cr.

It is especially advantageous if, according to a refinement of the present invention, a temperature sensor is provided in each case in the region of the melting crucible and the region of the nozzle pipe for regulating the output of the heaters of the melting crucible and the nozzle pipe. In this way, there is the possibility of optimally regulating the temperature in the nozzle pipe and in the melting crucible, which simultaneously ensures reduction of the energy required, because no unnecessarily high temperatures must be generated in one of the components in order to preclude low temperatures in the particular other component.

The attachment of the nozzle pipe to the melting crucible is implemented especially simply if the lower end of the nozzle pipe engages in the melting crucible with a diameter taper.

Another advantageous refinement of the present invention is that the nozzle pipe has a taper shaped like a truncated cone on its upper end having a coaxial filling opening, and a plunger whose height is adjustable may be introduced into this filling opening from above. Such a plunger has a double function. It is a closure part for the filling opening, so that during the operation of the vaporization device, vapor exits exclusively out of the vapor outlet of the nozzle pipe, and, in addition, the plunger holds the upper end of the nozzle pipe in coaxial alignment with the melting crucible.

The heat output of the heaters of the melting crucible and the nozzle pipe is directed to the melting crucible and the nozzle pipe if the nozzle pipe is enclosed concentrically by multiple reflectors which have a vapor passage window in the region of the vapor outlet.

The vapor device forms a thermally closed system and therefore does not load the coating chamber which accommodates it with thermal radiation if the reflectors are enclosed on the outside by a vaporizer housing which has external cooling pipes and has an exhaust opening in the region of the vapor passage window and the vapor outlet. Through this design, thermal insulation of the vapor deposition device using insulation material is unnecessary, so that the vapor deposition device is suitable for high vacuum, because there is no thermal insulation material having a large inner surface, from which the adsorbed gases desorb during operation, reach the vacuum chamber, and contaminate the coating material.

The cooling pipes do not obstruct the flee cross-section of the vapor passage window because they are aligned in a meander shape in the region of the nozzle pipe and have long pipe sections running in the lengthwise direction of the vaporization device which are alternately connected to one another above and below by a short pipe section in each case.

The cooling pipes for the housing in the region of the melting crucible may be positioned especially effectively there if they lead around the vaporizer housing in a spiral.

The vapor outlet allows the vapor to escape uniformly with vapor speeds sufficiently high to allow the vapor to reach the substrate reliably, if, according to another refinement of the present invention, the vapor outlet in the nozzle pipe is formed by multiple holes positioned one over another.

The melting crucible and the nozzle pipe are composed optimally for vaporizing silver or other metals which melt at high temperatures if the melting crucible and the nozzle pipe are made of graphite.

### BRIEF DESCRIPTION OF THE DRAWINGS

The present invention allows various embodiments. One of these is shown in the drawing and will be described in the following to further clarify its basic principle.

FIG. 1 shows a perpendicular section through a vaporization device according to the present invention,

FIG. 2 shows a perspective view of the vaporization device.

### DETAILED DESCRIPTION OF THE INVENTION

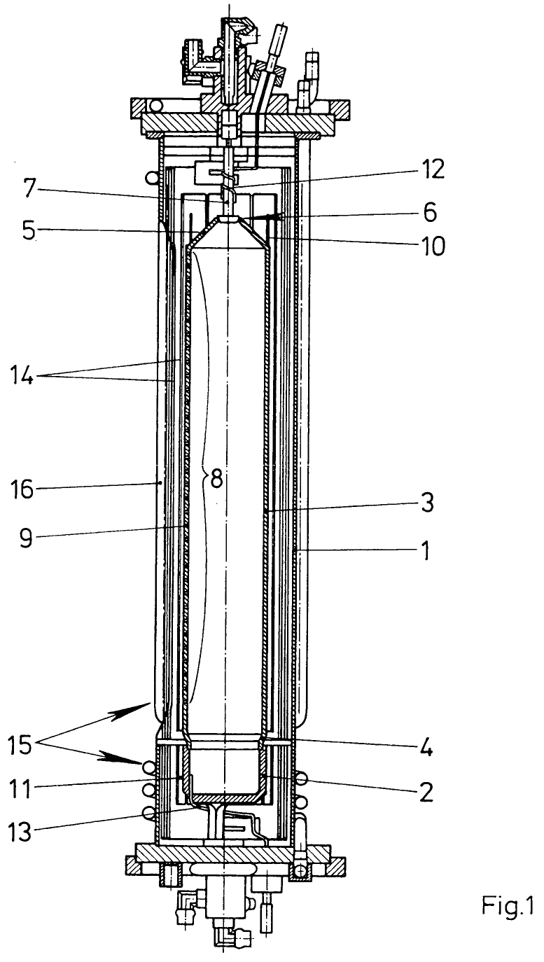

The vaporization device shown in longitudinal section in FIG. 1 has a vaporizer housing 1, in which a melting crucible 2 made of graphite is positioned upright. A nozzle pipe 3, which is also made of graphite, engages in this melting crucible 2 from above. The nozzle pipe 3 has a diameter taper 4 on its lower end, using which it engages in the melting crucible 2 from above. On its upper end, the nozzle pipe 3 has a taper 5 shaped like a truncated cone having a coaxial filling opening 6, in which a plunger 7 engages from above. The plunger 7 thus centers the upper end of the nozzle pipe 3 and presses the nozzle pipe 3 having its taper 4 against the melting crucible 2.

A vapor outlet 8 may be seen on the left side of the nozzle pipe 3 in FIG. 1, which is formed by multiple holes 9 positioned one over another in the wall of the nozzle pipe 3. An electrical heater 10 is used for heating the nozzle pipe 3, while a heater 11, independent thereof, is provided for heating the melting crucible 2. A temperature sensor 12 in the region of the plunger 7 is used for regulating the heater 10 of the nozzle pipe 3. Correspondingly, the temperature of the melting crucible wall is measured using a temperature sensor 13 to regulate the heater 11 of the melting crucible 2.

Cooling pipes 15 run along the outside of the vaporizer housing 1. These form a peripheral spiral in the region of the melting crucible 2. In the region of the nozzle pipe 3, they have straight pipe regions running in the lengthwise direction of the nozzle pipe 3.

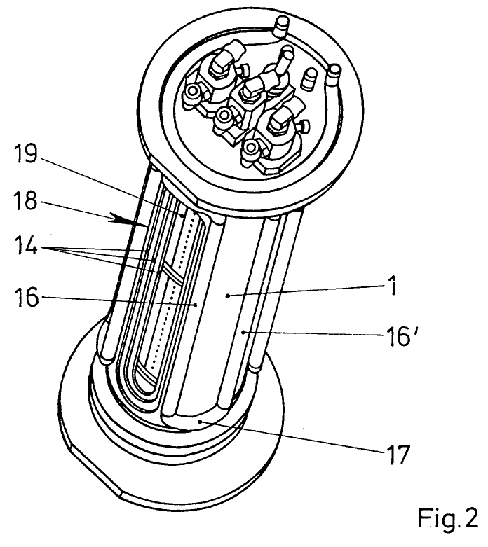

FIG. 2 shows how the pipe sections 16, 16′ running in the lengthwise direction are connected to one another in the lower region by a short pipe section 17 running around the circumference. Since the pipe sections 16 are alternately connected above and below by such short pipe sections 17, a meander-shaped pipe course results in the region of the nozzle pipe 3 shown in FIG. 1. Furthermore, an exhaust opening 17 may be seen in the vaporizer housing 1 in FIG. 2. The reflectors 14 have a corresponding vapor passage window 18 behind this exhaust opening 17.

What is claimed is:

1. A vapor deposition device for vapor deposition of vertically aligned regions of a substrate, in which an upright melting crucible, having a heater for melting and vaporizing material poured into the melting crucible, is positioned and which has a deflection device for deflecting the vapor flowing vertically out of the melting crucible horizontally toward the substrate,
characterized in that the deflection device is a nozzle pipe, placed from above on the melting crucible and sealable on top, which has a horizontal vapor outlet in its lateral surface, and the nozzle pipe has a heater which is independent of the heater of the melting crucible.

2. The vapor deposition device according to claim 1,
characterized in that a temperature sensor is provided in each case in the region of the melting crucible and in the region of the nozzle pipe for regulating the output of the heaters of the melting crucible and the nozzle pipe.

3. The vapor deposition device according to claim 1,
characterized in that the nozzle pipe engages in the melting crucible with a diameter taper on its lower end.

4. The vapor deposition device according to claim 1,
characterized in that the nozzle pipe has a taper shaped like a truncated cone on its upper end, having a coaxial filling opening, and a plunger, whose height is adjustable, may be introduced into this filling opening from above.

5. The vapor deposition device according claim 1,
characterized in that the nozzle pipe is enclosed concentrically by multiple reflectors, which have a vapor passage window in the region of the vapor outlet.

6. The vapor deposition device according to claim 1,
characterized in that the reflectors are externally enclosed by a vaporizer housing, which has cooling pipes on the outside and an exhaust opening in the region of the vapor passage window and the vapor outlet.

7. The vapor deposition device according to claim 6,
characterized in that the cooling pipes are aligned in a meander shape in the region of the nozzle pipe and have long pipe sections running in the lengthwise direction of the vaporization device, which are alternately connected to one another above and below by a short pipe section in each case.

8. The vapor deposition device according to claim 6,
characterized in that the cooling pipes lead in a spiral shape around the vaporizer housing in the region of the melting crucible.

9. The vapor deposition device according to claim 1,
characterized in that the vapor outlet in the nozzle pipe is formed by multiple holes positioned one over another.

10. The vapor deposition device according to claim 1,
characterized in that the melting crucible and the nozzle pipe are made of graphite.
